(19) United States
(12) Patent Application Publication
(10) Pub. No.: US 2023/0236088 A1
(43) Pub. Date: Jul. 27, 2023

(54) COMPUTER-AIDED METHOD AND DEVICE FOR PREDICTING SPEEDS FOR VEHICLES ON THE BASIS OF PROBABILITY

(71) Applicant: AVL LIST GMBH, Graz (AT)

(72) Inventors: Nico DIDCOCK, Graz (AT); Alexander WASSERBURGER, Wien (AT); Christoph HAMETNER, Wien (AT); Christian MAYR, Hadersdorf am Kamp (AT)

(21) Appl. No.: 18/247,535

(22) PCT Filed: Oct. 1, 2021
(86) PCT No.: PCT/AT2021/060355

§ 371 Date: Mar. 31, 2023

(30) Foreign Application Priority Data
Oct. 2, 2020 (AT) A 50847/2020

(51) Int. Cl. G01M 17/06; G06F 30/27; B60W 30/14; B60W 50/00

(52) U.S. Cl. CPC G01M 17/06; G06F 30/27; B60W 30/14; B60W 50/0097

(57) ABSTRACT

The invention relates to a computer-aided method for generating a drive cycle for a vehicle which is suitable for simulating a driving operation, in particular a real driving operation. The computer-aided method comprises establishing a state vector of the drive cycle for a current time interval from a past speed curve, providing an acceleration prediction model, determining an acceleration value in consideration of probabilities resulting from the acceleration prediction model and the state vector, integrating the determined acceleration value over the current time interval in order to obtain a predicted speed value for a next future time interval, and appending the predicted speed value to the past speed curve in order to generate the drive cycle. Furthermore, the invention relates to a device for generating a drive cycle for a vehicle which is suitable for simulating a driving operation, in particular a real driving operation, and means for establishing a state vector of the drive cycle for a current time interval from a past speed curve, means for determining an acceleration value in consideration of probabilities resulting from the acceleration prediction model and the state vector, means for integrating the determined acceleration value over the current time interval in order to obtain a predicted speed value for a next future time interval, and means for appending the predicted speed value to the past speed curve in order to generate the drive cycle.

The invention relates to a computer-aided method and a device for generating a drive cycle for a vehicle which is suitable for simulating a driving operation, in particular a real driving operation.

Emission regulations for vehicles with combustion engines are subject to ongoing changes aimed at factoring in driving conditions which are becoming increasingly closer to actual driving conditions on the road. One such emission regulation example is the European Union's regulation on the testing procedures for vehicle emissions under actual driving conditions, so-called Real Driving Emissions (RDE). These test procedures are for example part of the approval procedure on vehicle types. Consequently, emission tests are no longer to occur exclusively on a vehicle test bench with generally defined drive cycles but instead need to be performed under real driving conditions in order to take, for example, the influence of real traffic conditions and a driver's actual driving behavior into account.

For example, routes involving different speed ranges and minimum or maximum stop times must thus be included in an RDE-compliant drive cycle serving as the basis for a directive-compliant emission determination. However, emission regulations aimed at factoring in real driving conditions on the road allow for a plurality of different drive cycles, which entails an enormous amount of testing for vehicle manufacturers during the vehicle development process. In order to be able to determine a vehicle's consumption under real driving conditions, consumption is typically determined for approximately 1000 RDE-compliant drive cycles. This testing effort can be reduced by simulating a plurality of different guideline-compliant drive cycles which take realistic driving behavior into account.

In order to create such drive cycles, Markov chains or neural networks can be used to simulate drive cycles. However, drive cycles generated this way exhibit significant deviations from drive cycles measured under real road conditions. Alternatively, short routes measured under real road conditions can be combined together in different ways in order to generate a drive cycle. However, drive cycles generated this way are relatively similar to each other and thus simply provide insufficient variability for determining a vehicle's actual average consumption.

One task of the present invention is that of generating a plurality of different drive cycles which correspond to a vehicle's real driving behavior.

This task is solved by a computer-aided method and a device according to the independent claims. Preferential embodiments are claimed in the subclaims.

A first aspect of the invention relates to a computer-aided method for generating a drive cycle for a vehicle which is suitable for simulating a driving operation, in particular a real driving operation. The computer-aided method comprises establishing a state vector of the drive cycle for a current time interval from a past speed curve, providing an acceleration prediction model, determining an acceleration value in consideration of probabilities resulting from the acceleration prediction model and the state vector, integrating the determined acceleration value over the current time interval in order to obtain a predicted speed value for a next future time interval, and appending the predicted speed value to the past speed curve in order to generate the drive cycle.

A drive cycle within the meaning of the invention is in particular a time interval to which a constant speed value is assigned or a chronological sequence of multiple time intervals, each of which being assigned a constant speed value.

A current time interval of a drive cycle within the meaning of the invention is in particular a time interval immediately following past drive cycle time intervals and to which a current speed value, which can be a finite value or zero, is assigned.

A past speed curve within the meaning of the invention is in particular a current time interval to which a speed value is assigned and/or a past time interval to which a speed value is assigned and/or a plurality of past time intervals, each of which being assigned a constant speed value. A speed value can be a finite value or zero.

An acceleration value within the meaning of the invention is a positive value in the case of positive acceleration or a negative value in the case of negative acceleration, also referred to herein as deceleration.

A state vector of a drive cycle for a current time interval within the meaning of the invention is in particular a vector with components corresponding to one or more speed values and/or one or more acceleration values and/or one or more acceleration change values and/or one or more values indicating a number of time intervals.

An acceleration prediction model within the meaning of the invention is in particular a model for determining one or more acceleration values for a current time interval or for one or more time intervals chronologically following the current time interval. An acceleration prediction model within the meaning of the invention can also be referred to as a conditional acceleration prediction (CAP).

The invention is based in particular on the approach of establishing a state vector representing the current state of a drive cycle at a current time interval from a past speed curve; i.e. at least one speed value associated with a current time interval and/or at least one past time interval, and using the state vector and a probability-based acceleration prediction model to determine an acceleration value for the current time interval. By integrating the thusly determined acceleration value over the current time interval, a predicted speed value is obtained for a future time interval which is appended to the past speed curve.

Compared to the prior art, the computer-aided method for generating a drive cycle for a vehicle according to the present invention has the advantage of any number of drive cycles being able to be generated which, on the one hand, have dissimilar speed curves and, on the other hand, show great resemblance to drive cycles measured under real conditions due to the use of the acceleration prediction model.

In one preferential embodiment of the method for generating a drive cycle, the determining of an acceleration value in consideration of probabilities resulting from the acceleration prediction model and the state vector comprises establishing a probability value for a current scenario of an acceleration and a probability value for a current scenario of a deceleration and a probability value for a current scenario of a state of constant speed by means of the acceleration prediction model as a function of the state vector. The determining of an acceleration value in consideration of probabilities furthermore comprises randomly selecting an acceleration, deceleration or constant speed scenario for the current time interval based on the probability values for current acceleration, deceleration and constant speed scenarios and/or establishing a probability distribution of acceleration values of the randomly selected scenario and a random selecting of an acceleration value for the current time interval based on the probability distribution of acceleration values of the randomly selected scenario by means of the acceleration prediction model as a function of the state vector.

A current scenario within the meaning of the invention is in particular an acceleration, a deceleration or a state of constant speed in a current time interval.

A random selection within the meaning of the invention is in particular a random sampling, respectively a random sampling in the statistical sense.

The random selecting of an acceleration, deceleration or constant speed scenario based on probability values for current acceleration, deceleration and constant speed scenarios as well as the random selecting of an acceleration value for the current time interval based on a probability distribution of acceleration values has the following advantages: A plurality of drive cycles bearing no resemblance to each other can be generated from the same past speed curve using the acceleration prediction model. Moreover, they provide sufficient variability for determining the average consumption of a vehicle under real driving conditions.

In a further preferential embodiment of the method for generating a drive cycle, the drive cycle is generated by iteratively executing the method's work steps in the listed order and each predicted speed value being appended to the past speed curve from a previous iteration. This has the advantage of being able to generate a drive cycle of any length.

In a further preferential embodiment of the method for generating a drive cycle, multiple predicted speed values are in each case obtained for the same future time intervals based on the past speed curve so that statistical speed distributions are obtained for future time intervals. The statistical speed distributions for the future time intervals allow a statistical evaluation of the generated drive cycle. For example, a drive cycle can thereby be created which has speed values corresponding to the respective expected value of the statistical speed distributions.

In a further preferential embodiment of the method for generating a drive cycle, the state vector shows for a current time interval at least one current speed value and/or one or more past speed values and/or one or more acceleration values of one or more time intervals and/or one or more acceleration change values of one or more time intervals and/or a value corresponding to a number of time intervals pursuant to the duration of an ongoing acceleration maneuver and/or a value corresponding to a number of time intervals pursuant to the duration of an ongoing deceleration maneuver and/or a value corresponding to a number of time intervals pursuant to the duration of an ongoing constant speed state.

A time interval acceleration change within the meaning of the invention is in particular the difference between an acceleration value within the time interval and an acceleration value in a previous time interval.

An acceleration maneuver within the meaning of the invention is in particular an uninterrupted acceleration process of any acceleration values over one or more time intervals which started in the past; i.e. in a past time interval prior to the current time interval. An ongoing acceleration maneuver means that the acceleration maneuver continues up to the time interval immediately prior to the current time interval.

A deceleration maneuver within the meaning of the invention is in particular an uninterrupted process of deceleration of any negative acceleration values over one or more time intervals which started in the past; i.e. in a past time interval prior to the current time interval. An ongoing deceleration maneuver means that the deceleration maneuver continues up to the time interval immediately prior to the current time interval.

A constant speed state within the meaning of the invention is in particular the maintaining of a constant speed value over one or more time intervals which started in the past; i.e. in a past time interval prior to the current time interval. An ongoing state of constant speed means that the state of constant speed continues up to the time interval immediately prior to the current time interval.

Since the state vector of a current time interval comprises a value pursuant to the duration of an ongoing acceleration maneuver, a value pursuant to the duration of an ongoing deceleration maneuver and/or a value pursuant to the duration of an ongoing constant speed state, the duration of acceleration maneuvers, deceleration maneuvers and/or or the duration of a constant speed state within an already generated part of a drive cycle has an influence on the further course of the drive cycle.

Pursuant to the real driving behavior of a vehicle, the duration of an acceleration maneuver in the drive cycle's past has an influence on the probability established according to the present invention for the continuation of the acceleration maneuver in the current time interval and in future time intervals of a drive cycle. The same applies to deceleration maneuvers and constant speed states. The established probability distribution of acceleration values of a randomly selected scenario for a current time interval and future time intervals is also dependent on the duration of an acceleration maneuver, deceleration maneuver or constant speed state in the drive cycle's past. This has the advantage of further increasing the similarity of the generated drive cycle and drive cycles measured under real conditions.

In a further preferential embodiment of the method for generating a drive cycle, the acceleration value, which is determined in consideration of probabilities resulting from the acceleration prediction model and the state vector, is based on the duration of an ongoing acceleration maneuver, an ongoing deceleration maneuver or an ongoing state of constant speed. This has the advantage of the duration of an acceleration maneuver, a deceleration maneuver or a constant speed state being adapted to real driving conditions and thus being able to further increase the similarity between the generated drive cycle and drive cycles measured under real conditions.

In a further preferential embodiment of the method for generating a drive cycle, the past speed curve comprises at least one speed value. The at least one speed value can be a finite value or zero. This has the advantage of a drive cycle being able to be generated from a single speed value.

In a further preferential embodiment of the method for generating a drive cycle, the current scenario of an acceleration and/or the current scenario of a deceleration and/or the current scenario of a constant speed state each exhibit a probability distribution of acceleration values. This enables a statistical evaluation of the generated drive cycle. For example, a drive cycle can thereby be created with speed values based on acceleration values corresponding to the respective expected value of the probability distributions of acceleration values in the individual time intervals.

A further preferential embodiment of the method for generating a drive cycle sets an expected value of the probability distribution of acceleration values based on the past speed curve. Preferably, the expected value of the modeled probability distribution is derived on the basis of the current speed value and a past speed value. Preferably, the expected value of the modeled probability distribution is set on the basis of the current speed value and the immediately preceding current speed value. This has the advantage of the speed curve of the drive cycle exhibiting a chronologically smooth or constant progression. This thereby prevents abrupt jumps in the speed curve of the generated drive cycle over time, which further increases its similarity to drive cycles measured under real conditions.

In a further preferential embodiment of the method for generating a drive cycle, the acceleration prediction model is based on a statistical evaluation of measured driving data of at least one real vehicle, wherein preferably the measured driving data of the at least one real vehicle only comprises a chronological sequence of speed values. Preferably, the driving data of the real vehicle measured under real driving conditions is used for model training, particularly for the determining of model parameters. This has the advantage of increasing the similarity between the drive cycles generated using the acceleration prediction model and drive cycles measured under real conditions.

A further aspect of the invention relates to a method for driving a vehicle using an adaptive cruise control system, in particular a driver assistance system, particularly for predictive driving functions, wherein the drive cycle of the vehicle driving in front of the vehicle is determined using a computer-aided method according to one of the cited embodiments.

In one preferential embodiment of the method for driving a vehicle, the distance between the vehicle and the vehicle in front is not used as an input value or boundary condition for the adaptive cruise control, wherein preferably the distance between the vehicle and the vehicle in front is based on a cost function solution or cost optimization function solution respectively. The distance between the vehicle and the vehicle in front is thus not a constant variable, which has the advantage of the distance being able to be adapted to current traffic conditions.

In a further preferential embodiment of the method for driving a vehicle, multiple predicted speed values are obtained for the same future time intervals based on the past speed curve so that statistical speed distributions are obtained for future time intervals, wherein safety conditions for driving the vehicle are derived from the statistical speed distributions. In particular among these safety conditions for driving the vehicle is determining the minimum distance needing to be maintained between the vehicle and the vehicle in front in order to prevent the two vehicles from colliding. This thereby enables an increase in safety when driving the vehicle.

A further aspect of the invention relates to a method for generating a drive cycle for a vehicle which is suitable for use by driver assistance systems, in particular for predictive driving functions, and comprises the work steps of a method for generating a drive cycle according to one of the cited embodiments.

A further aspect of the invention relates to a method for analyzing at least one component of a motor vehicle, wherein the at least one component or the motor vehicle is subjected to a real or simulated test operation based on at least one drive cycle determined using a method for generating a drive cycle according to one of the cited embodiments.

Further preferably, the method for analyzing at least one motor vehicle component comprises checking the compliance of the multiple predicted speed values with at least one boundary condition, in particular Real Driving Emissions (RDE) guidelines, after a defined number of iterations, wherein the check in particular recurs periodically at the end of each of the specific number of iterations, wherein the specific number of iterations in particular corresponds to a predefined total time interval, e.g. of 5 minutes. This has the advantage of being able to generate RDE guideline-compliant drive cycles.

Further preferably, the method for analyzing at least one motor vehicle component comprises correcting the probability value for a current acceleration scenario and/or the probability value for a current deceleration scenario and/or the probability value for a current constant speed state scenario for the current time interval based on the check and/or correcting the acceleration value for the current time interval based on the check.

This has the advantage of being able to generate RDE guideline-compliant drive cycles.

A further aspect of the invention relates to a computer program product containing instructions which, when executed by a computer, prompts it to execute the steps of a method according to one of the cited embodiments.

A further aspect of the invention relates to a computer-readable medium on which a computer program product according to one of the cited embodiments is stored.

A further aspect of the invention relates to a device for generating a drive cycle for a vehicle which is suitable for simulating a driving operation, in particular a real driving operation, and means for establishing a state vector of the drive cycle for a current time interval from a past speed curve, means for providing an acceleration prediction model, means for determining an acceleration value in consideration of probabilities resulting from the acceleration prediction model and the state vector, means for integrating the selected acceleration value over the current time interval in order to obtain a predicted speed value for a next future time interval, and means for appending the predicted speed value to the past speed curve in order to generate the drive cycle.

A means within the meaning of the invention can be hardware and/or software and comprising in particular particularly a digital processing unit, in particular a microprocessor unit (CPU), preferably data-connected or respectively signal-connected to a memory or bus system, and/or one or more programs or program modules. The CPU can thereby be designed to process commands implemented as a program stored in a memory system, capture input signals from a data bus and/or send output signals to a data bus. A memory system can comprise one or more, in particular different, storage media, particularly optical, magnetic solid-state and/or other non-volatile media. The program can be provided so as to embody or be capable of performing the methods described herein so that the CPU can execute the steps of such methods and can thus in particular control and/or monitor a reciprocating piston engine.

Further features and advantages derive from the following description in conjunction with the figures. The figures show at least partly schematically:

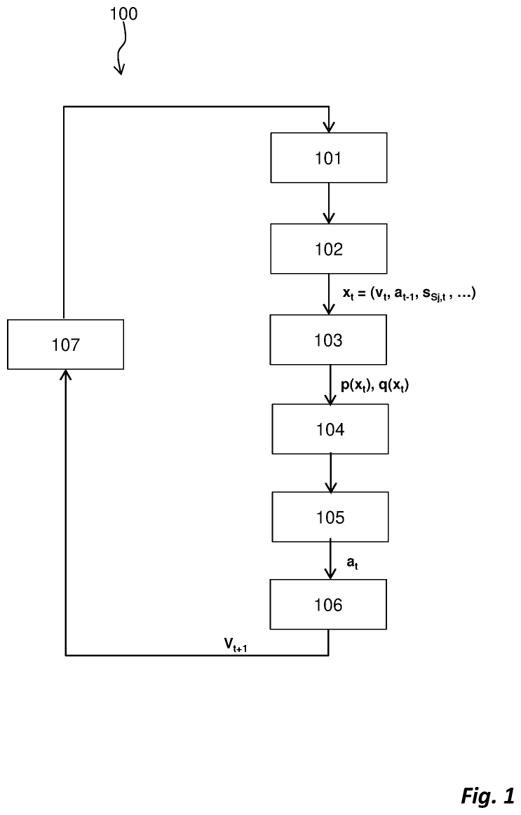

FIG. 1 a preferential exemplary embodiment of an inventive computer-aided method for generating a drive cycle for a vehicle, wherein the method is suitable for simulating a real driving operation;

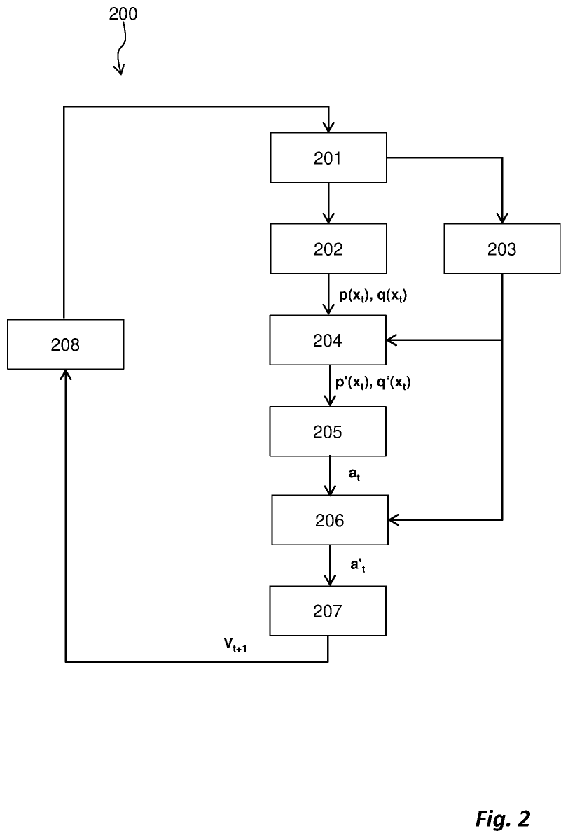

FIG. 2 a preferential exemplary embodiment of an inventive computer-aided method for generating an RDE-compliant drive cycle for a vehicle; and

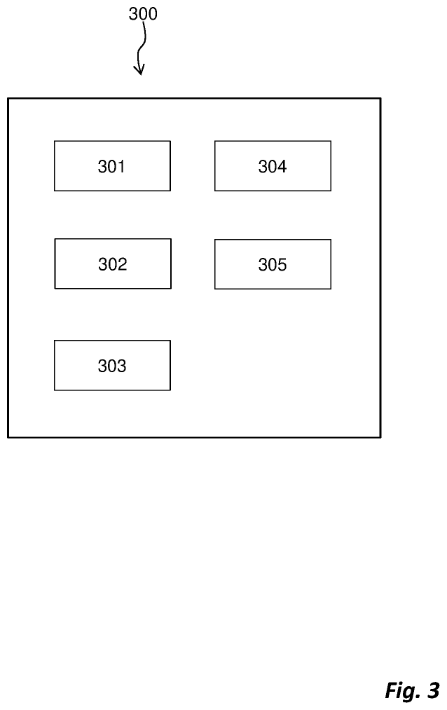

FIG. 3 a preferential exemplary embodiment of a device for generating a drive cycle for a vehicle which is suitable for simulating a real driving operation.

FIG. 1 shows a preferential exemplary embodiment of a computer-aided method 100 according to the invention for generating a drive cycle for a vehicle, wherein the method 100 is suitable for simulating a real driving operation.

Step 101 of the method 100 has past data being provided. The past data represents past speed data or a past speed curve and comprises or consists of speed values which are respectively associated with consecutive defined time intervals. The defined time intervals can be constant time intervals or can vary in length. The past data can comprise or consist of a single speed value associated with a single time interval. This single speed value can also be zero. The most recent speed value of the past speed curve is assigned to a current time interval.

In step 102, the state vector xₜ is established for the current time interval from the past speed data or speed curve respectively. The state vector xₜ has as components the current speed value vₜ of the current time interval t, the acceleration value aₜ₋₁ of the time interval t−1 immediately prior to the current time interval t, a value s_{a,t} corresponding to the number of time intervals in which an acceleration maneuver occurs immediately prior to the current time interval, a value s_{e,t} corresponding to the number of time intervals in which a deceleration maneuver occurs immediately prior to the current time interval, as well as a value s_{k,t} corresponding to the number of time intervals in which a state of constant speed was maintained immediately prior to the current time interval.

The s_{j,t} designation used in FIG. 1 refers to the three values of s_{a,t}, s_{e,t} and s_{k,t}, wherein index j can either assume a for an acceleration maneuver, e for a deceleration maneuver or k for a state of constant speed. The state vector can have further components or other components corresponding to speed values, acceleration values, changes in acceleration values, or a number of time intervals.

In step 103, a probability value p(xₜ) for a current acceleration scenario and a probability value q(xₜ) for a current deceleration scenario are established from the state vector by means of an acceleration prediction model. The probability value y for a constant speed state then results preferably from the following relationship y=1−p(xₜ)−q(xₜ). The acceleration prediction model is based preferably on a statistical evaluation of measured driving data of a real vehicle, wherein the measured driving data consists exclusively of a chronological sequence of speed values associated with chronologically consecutive time intervals.

In step 104, based on the probability values p(xₜ), q(xₜ) and 1−p(xₜ)−q(xₜ) established in step 103, a random selection of one of three scenarios then follows in the sense of a statistical random sampling; i.e. an acceleration scenario, a deceleration scenario or the scenario of the state of constant speed.

A probability distribution of acceleration values is established for the randomly selected scenario by way of the acceleration prediction model as a function of the state vector, preferably a continuous probability distribution is modeled thereto. Further preferably, each possible acceleration value within the randomly selected scenario can be assigned a probability.

In step 105, a random selection in the sense of a statistical random sampling of any random acceleration value aₜ is made for the current time interval t from the established probability distribution of the randomly selected scenario.

In step 106, the randomly selected acceleration value aₜ is integrated over the current time interval tin order to obtain a next predicted speed value vₜ₊₁ for a next time interval t+1 in the future.

In step 107, the new speed value vₜ₊₁ is appended to the past speed curve. The new speed value vₜ₊₁ for time interval t+1 is thereafter treated as the current time interval in a second iteration of the method in step 102. Iteratively running through steps 102 to 107 creates a drive cycle which, due to the nature of the acceleration prediction model, is similar to a drive cycle measured under real conditions.

FIG. 2 shows a preferential exemplary embodiment of an inventive computer-aided method 200 for generating an RDE-compliant drive cycle for a vehicle.

Step 201 of method 200 is identical to the above-described step 101 of method 100. Past speed data is provided.

Step 202 of method 200 includes the above-described steps 102 and 103 of method 100. The state vector xₜ is established for the current time interval from the past speed curve. A probability value p(xₜ) for a current acceleration scenario and a probability value q(xₜ) for a current deceleration scenario are established from the state vector by means of an acceleration prediction model.

After multiple predicted speed values have been obtained and appended to the past speed curve through the iterative execution of method 100, a checking of the previously predicted; i.e. previously generated, speed values for compliance with the criteria of the RDE guidelines recurs periodically in step 203 of method 200 at the end of a defined number of iterations of method 100. For example, this periodically recurring check can in each case take place after a number of time intervals corresponding to the elapsing of a five-minute time span of the drive cycle, although other spans of time for the periodic check are also possible.

After the probability values p(xₜ) and q(xₜ) for a current acceleration scenario and for a current deceleration scenario have been established in step 202, should the checking in step 203 show that the previously predicted speed values appended to the past speed curve do not adhere to the criteria of the RDE guidelines, the established probability values p(xₜ) and q(xₜ) are corrected accordingly in step 204.

The current acceleration scenario or deceleration scenario respectively thus receives corrected probability values p′(xₜ) and q′(xₜ). Should, for example, the checking in step 203 show that the previously predicted speed values and corresponding time intervals do not meet the criteria of the RDE guidelines for the duration of highway driving at increased speed, the probability for an acceleration scenario is increased by the correction and the probability for a deceleration scenario is correspondingly reduced in step 204.

In step 205, one of the three scenarios is thereafter randomly selected; i.e. an acceleration scenario, a deceleration scenario or a scenario of the state of constant speed based on the probability values p′(xₜ), q′(xₜ) and 1−p′(xₜ)−q′(xₜ) corrected via step 204 and a random selection of any random acceleration value aₜ is made from the established probability distribution of the randomly selected scenario as described in the context of method 100.

Alternatively or additionally to the correction in step 204, the randomly selected acceleration value can be corrected in step 206 pursuant to the step 203 check, whereby corrected acceleration value a′ₜ is generated.

In step 207, the corrected acceleration value a′ₜ is integrated over the current time interval t in order to obtain a next predicted speed value vₜ₊₁ for a next time interval t+1 in the future.

In step 208, the new speed value vₜ₊₁ is appended to the past speed curve. The new speed value vₜ₊₁ for time interval t+1 is thereafter treated as the current time interval in the next iteration of the method 200 in step 202. Iteratively running through steps 202 to 208 creates a drive cycle which, due to the nature of the acceleration prediction model, is similar to a drive cycle measured under real conditions and is in compliance with the RDE guidelines.

FIG. 3 shows a preferential exemplary embodiment of a device 300 for generating a drive cycle for a vehicle which is suitable for simulating a real driving operation. The device for generating the drive cycle for a vehicle comprises means 301 for establishing a state vector of the drive cycle for a current time interval from a past speed curve. Furthermore, the device for generating the drive cycle comprises means 302 for providing an acceleration prediction model, means 303 for determining an acceleration value in consideration of probabilities resulting from the acceleration prediction model and the state vector, means 304 for integrating the determined acceleration value over the current time interval in order to obtain a predicted speed value for a next future time interval, and means 305 for appending the predicted speed value to the past speed curve in order to generate the drive cycle.

It should be noted that the exemplary embodiments are only examples not intended to limit the scope of protection, application and configuration in any way. Rather, the foregoing description is to provide the person skilled in the art with a guideline for implementing at least one exemplary embodiment, whereby various modifications can be made, particularly as regards the function and arrangement of the described components, without departing from the scope of protection resulting from the claims and equivalent combinations of features.

### LIST OF REFERENCE NUMERALS

300 device for generating a drive cycle for a vehicle
301 means for establishing a state vector of the drive cycle
302 means for providing an acceleration prediction model
303 means for determining an acceleration value
304 means for integrating the determined acceleration value
305 means for appending the predicted speed value to the past speed curve

What is claimed is:

1. A computer-aided method for generating a drive cycle for a vehicle which is suitable for simulating a driving operation, in particular a real driving operation, comprising the following work steps:
establishing a state vector of the drive cycle for a current time interval from a past speed curve;
providing an acceleration prediction model;
determining an acceleration value in consideration of probabilities resulting from the acceleration prediction model and the state vector;
integrating the determined acceleration value over the current time interval in order to obtain a predicted speed value for a next future time interval; and
appending the predicted speed value to the past speed curve in order to generate the drive cycle.

2. The method according to claim 1, wherein the determining of an acceleration value in consideration of probabilities resulting from the acceleration prediction model and the state vector comprises the following work steps:
establishing a probability value for a current scenario of an acceleration and a probability value for a current scenario of a deceleration and a probability value for a current scenario of a state of constant speed by means of the acceleration prediction model as a function of the state vector; and
randomly selecting an acceleration, deceleration or constant speed scenario for the current time interval based on the probability values for current acceleration, deceleration and constant speed scenarios; and/or
establishing a probability distribution of acceleration values of the randomly selected scenario by means of the acceleration prediction model as a function of the state vector; and
randomly selecting an acceleration value for the current time interval based on the probability distribution of acceleration values of the randomly selected scenario.

3. The method according to claim 1, wherein the drive cycle is generated by iteratively executing the work steps of the method in the listed order and each predicted speed value being appended to the past speed curve from a previous iteration.

4. The method according to claim 1, wherein multiple predicted speed values are in each case obtained for the same future time intervals based on the past speed curve so that statistical speed distributions are obtained for future time intervals.

5. The method according to claim 1, wherein the state vector for a current time interval comprises at least one of the following components:
a current speed value, one or more past speed values, one or more acceleration values of one or more time intervals, one or more acceleration change values of one or more time intervals, a value corresponding to a number of time intervals pursuant to the duration of an ongoing acceleration maneuver, a value corresponding to a number of time intervals pursuant to the duration of an ongoing deceleration maneuver and a value corresponding to a number of time intervals pursuant to the duration of an ongoing constant speed state.

6. The method according to claim 1, wherein the acceleration value determined in consideration of probabilities resulting from the acceleration prediction model and the state vector is based on the duration of an ongoing acceleration maneuver, an ongoing deceleration maneuver or an ongoing state of constant speed.

7. The method according to claim 1, wherein the past speed curve comprises at least one speed value.

8. The method according to claim 1, wherein the current scenario of an acceleration and/or the current scenario of a deceleration and/or the current scenario of a constant speed state each exhibit a probability distribution of acceleration values.

9. The method according to claim 2, wherein an expected value of the probability distribution of acceleration values is set based on the past speed curve.

10. The method according to claim 1, wherein the acceleration prediction model is based on a statistical evaluation of measured driving data of at least one real vehicle, wherein preferably the measured driving data of the at least one real vehicle only comprises a chronological sequence of speed values.

11. A method for driving a vehicle using an adaptive cruise control system, in particular a driver assistance system, particularly for predictive driving functions, wherein the drive cycle of the vehicle driving in front of the vehicle is determined using the method according to claim 1.

12. The method according to claim 11, wherein multiple predicted speed values are obtained for the same future time intervals based on the past speed curve so that statistical speed distributions are obtained for future time intervals, wherein safety conditions for driving the vehicle are derived from the statistical speed distributions.

13. A method for generating a drive cycle for a vehicle which is suitable for use by driver assistance systems, in particular for predictive driving functions, and comprises the work steps of claim 1.

14. A method for analyzing at least one component of a motor vehicle, wherein the at least one component or the motor vehicle is subjected to a real or simulated test operation based on at least one drive cycle determined using a method according to claim 1.

15. The method according to claim 14, wherein the method comprises the following further work steps:
checking the compliance of the multiple predicted speed values with at least one boundary condition, in particular Real Driving Emissions guidelines, after a defined number of iterations, wherein the check in particular recurs periodically at the end of each of the specific number of iterations, wherein the specific number of iterations in particular corresponds to a predefined total time interval, preferably of approximately 5 minutes.

16. The method according to claim 15, wherein the method comprises the following further work steps:
correcting the probability value for a current acceleration scenario and/or the probability value for a current deceleration scenario and/or the probability value for a current constant speed state scenario for the current time interval based on the check; and/or
correcting the acceleration value for the current time interval based on the check.

17. A computer program product having instructions which, when executed by a computer, prompts it to execute the steps of a method according to claim 1.

18. A computer-readable medium on which a computer program product according to claim 17 is stored.

19. A device for generating a drive cycle for a vehicle which is suitable for simulating a driving operation, in particular a real driving operation, comprising:
means for establishing a state vector of the drive cycle for a current time interval from a past speed curve;
means for providing an acceleration prediction model;
means for determining an acceleration value in consideration of probabilities resulting from the acceleration prediction model and the state vector;
means for integrating the determined acceleration value over the current time interval in order to obtain a predicted speed value for a next future time interval; and
means for appending the predicted speed value to the past speed curve in order to generate the drive cycle.
